(19) United States
(12) Patent Application Publication
(10) Pub. No.: US 2014/0035139 A1
(43) Pub. Date: Feb. 6, 2014

(54) SEMICONDUCTOR DEVICE AND METHOD OF MANUFACTURING THE SAME

(71) Applicant: RENESAS ELECTRONICS CORPORATION, Kanagawa (JP)

(72) Inventor: Osamu KATO, Kanagawa (JP)

(21) Appl. No.: 13/910,497

(22) Filed: Jun. 5, 2013

(30) Foreign Application Priority Data
Aug. 3, 2012 (JP) 2012-173168

(51) Int. Cl. H01L 23/538; H01L 21/768

(52) U.S. Cl. CPC H01L 23/5383; H01L 21/76895
USPC 257/750; 438/612

(57) ABSTRACT

To prevent cracking in a passivation film by oxidation of an antireflection film, a semiconductor device includes a metal wiring layer for a pad, an insulating layer which is provided so as to cover the metal wiring layer and which includes an opening portion from which a part of a surface of the metal wiring layer is exposed. The metal wiring layer includes a first metal layer, and a second metal layer which is provided over the first metal layer except for the opening portion and which is thinner than the first metal layer. The metal wiring layer has a groove portion in a predetermined region except for the opening portion. The first metal layer protrudes, in an eaves shape, to the groove portion. The second metal layer on a side wall inside the groove portion is thinner than the second metal layer outside the groove portion.

### CROSS-REFERENCE TO RELATED APPLICATION

The disclosure of Japanese Patent Application No. 2012-173168 filed on Aug. 3, 2012 including the specification, drawings and abstract is incorporated herein by reference in its entirety.

### BACKGROUND

The present invention relates to a semiconductor device, a semiconductor device including, for example, a pad.

An aluminum alloy whose main raw material is aluminum is often used for a wiring layer constituting a bonding pad of a semiconductor device. Since the aluminum alloy has high reflectance, there is a risk that a patterning abnormality occurs in a lithography process. In order to prevent the patterning abnormality, the aluminum alloy is used as a layered structure with an antireflection film. As the antireflection film, titanium nitride is often used. A passivation film is formed over the antireflection film. A pad opening portion which is an opening portion for a bonding pad is provided in the passivation film. The antireflection film is removed from the pad opening portion. As a result, the aluminum alloy is exposed from the pad opening portion.

As one of quality verification tests of a semiconductor device, there is a high-temperature and high-humidity bias testing in which a voltage is applied under an environment of high-temperature and high-humidity for a long time. While the testing is performed, water may penetrate into the pad opening portion through a sealing resin of the semiconductor device. In this case, if a voltage is applied to the aluminum alloy at the pad opening portion, the titanium nitride of the antireflection film which is slightly exposed between the passivation film surrounding the pad opening portion and the aluminum alloy below the passivation film is oxidized, so that titanium oxide may be formed. This oxidation phenomenon not only occurs at the portion where the titanium nitride is exposed, but also may progress to an internal region covered by the passivation film. The process in which the titanium nitride is oxidized is accompanied by a volume expansion, and when the oxidized region expands, a crack may be generated in the passivation film by the stress due to the volume expansion. When a crack is generated in the passivation film and the crack propagates to a layer below the passivation film, water may penetrate along the crack. When the water penetrates, there is a risk of inducing defects such as change of film quality of a low dielectric constant film constituting an interlayer insulating film and corrosion of wiring metal constituting a wiring layer. Therefore, the cracking of the passivation film is required to be prevented.

Thus, in a semiconductor device which is assumed to be used for a long time and required to have high quality, a mechanism as described below is required. That is, when titanium nitride is used as the antireflection film of the wiring layer of the aluminum alloy (pad wiring layer or pad aluminum wiring layer) constituting a bonding pad, the mechanism suppresses the oxidation of the titanium nitride or prevents cracking of the passivation film even if the titanium nitride is oxidized. That is, when an antireflection film with low reflectance is formed over a pad wiring layer with high reflectance, there is required a mechanism that prevents a phenomenon in which the antireflection film is oxidized by water and the volume of the antireflection film expands, thereby a crack being generated in the passivation film. In contrast, there is a strong need to reduce the cost of a semiconductor device, and thus it is necessary to realize the mechanism at low cost.

As a technique to prevent the phenomenon in which a crack is generated in the passivation film by the oxidation of the titanium nitride, a semiconductor device is disclosed in Japanese Patent Laid-Open No. 2010-272621 (US 2010/0295044(A1)) (Patent Document 1). In this semiconductor device, the titanium nitride is removed from a region larger than the pad opening portion. Specifically, after the pad aluminum wiring layer is formed, a titanium nitride removing process is added and the titanium nitride is removed from a region larger than the pad opening portion. Thereafter, the passivation film is formed and the pad opening portion is formed in the passivation film. By the adoption of such a structure, the titanium nitride is not exposed between the bottom of the pad opening portion in the passivation film and the aluminum alloy below the bottom of the pad opening portion. As a result, it is possible to prevent the phenomenon in which the crack is generated in the passivation film by the oxidation of the titanium nitride.

Moreover, as a technique to prevent the phenomenon in which a crack is generated in the passivation film by the oxidation of the titanium nitride, a semiconductor integrated circuit device is disclosed in Japanese Patent Laid-Open No. 2010-251537 (US 2010/0264414(A1)) (Patent Document 2). In this semiconductor integrated circuit device, a region where the titanium nitride is removed in a ring shape that surrounds the pad opening portion, is provided. In this case, the titanium nitride is exposed between the bottom of the pad opening portion in the passivation film and the aluminum alloy below the bottom of the pad opening portion. However, even if the titanium nitride is oxidized, the oxidized region can be limited to a narrow range. Since the oxidized region is limited, no crack is generated. By the adoption of such a passivation structure in which no crack is generated, it is possible to prevent the phenomenon in which the crack is generated in the passivation film by the oxidation of the titanium nitride.

Furthermore, as a technique to prevent the phenomenon in which a crack is generated in the passivation film by the oxidation of the titanium nitride, a semiconductor device is disclosed in Japanese Patent Laid-Open No. 2006-303452 (US 2006/0249845(A1)) (Patent Document 3). In this semiconductor device, an insulating film is additionally formed so as to cover the exposed titanium nitride. Specifically, a process of forming an insulating film after forming the pad opening portion and a process of etching the insulating film so as to open the pad opening portion again while covering the titanium nitride exposed to the pad opening portion are added. By the adoption of such a structure, the titanium nitride is not exposed between the bottom of the pad opening portion in the passivation film and the aluminum alloy below the bottom of the pad opening portion. As a result, it is possible to prevent the phenomenon in which the crack is generated in the passivation film by the oxidation of the titanium nitride.

As a related technique, a semiconductor device is disclosed in Japanese Patent Laid-Open No. 2007-103593 (Patent Document 4). This semiconductor device includes a conducting film, a protective film, and an opening. The conducting film includes a first metal film and a second metal film which is deposited over the first metal film and which is different from the first metal film. The protective film is formed of an insulating film which is deposited over an upper portion of the conducting film. The opening exposes the first metal film by removing the protective film and the second metal film. A region obtained by removing the protective film is inside a region obtained by removing the second metal film.

In addition, a semiconductor device is disclosed in Japanese Patent Laid-Open No. 2010-080772 (US 2010/0078780(A1)) (Patent Document 5). This semiconductor device includes wiring, an interlayer insulating film, an in-opening metal film, a surface metal film, and a conduction securing film. The interlayer insulating film is formed over the wiring, and includes an opening that reaches the wiring from the surface of the interlayer insulating film. The in-opening metal film is formed over the wiring inside the opening and is formed of a metal material including aluminum. The surface metal film is formed over the interlayer insulating film and is formed of the above metal material. The conduction securing film is formed over the side surface of the opening, and secures conduction between the in-opening metal film and the surface metal film.

### SUMMARY

The techniques disclosed in the above-mentioned Patent Document 1, Patent Document 2 and the like can prevent the phenomenon in which the crack is generated in the passivation film by the oxidation of the titanium nitride. However, in order to obtain a semiconductor device in which these techniques are used, it is necessary to newly add a lithography process and an etching process in the process of manufacturing the semiconductor.

In addition, the technique disclosed in the above-mentioned Patent Document 3 and the like can prevent the phenomenon in which the crack is generated in the passivation film by the oxidation of the titanium nitride. However, also in order to obtain a semiconductor device in which the technique is used, it is necessary to newly add a film formation process, a lithography process, and an etching process in the process of manufacturing the semiconductor.

As described above, through the use of the techniques of related arts, it is possible to prevent the phenomenon in which the titanium nitride provided between the bottom of the pad opening portion of the passivation film and the aluminum alloy below the bottom of the pad opening portion is oxidized and the crack is generated in the passivation film. However, it is necessary to add a new process in order to achieve the above. As a result, a problem occurs in which the manufacturing cost of the semiconductor device increases, the throughput decreases and the like. A technique is desired in which a new process need not be added in preventing the cracking in the passivation film by the oxidation of the titanium nitride. There is required a technique that prevents, without adding a new process, the phenomenon in which the crack is generated in the passivation film by the oxidation of the antireflection film exposed between the bottom of the pad opening portion of the passivation film and the pad wiring layer below the bottom of the pad opening portion.

The other problems and the new feature will become clear from the description of the present specification and the accompanying drawings.

In a semiconductor device including a pad, when a pad wiring layer, an antireflection film, and an insulating layer including a pad opening portion are provided in this order, a groove portion is formed in a pad wiring layer near a region where the pad opening portion is formed and the antireflection film is formed over the pad wiring layer. The film thickness of the antireflection film over the inner wall of the groove portion is smaller than that of the antireflection film outside the groove portion.

According to an embodiment described above, in a semiconductor device including a pad, it is possible to prevent, without adding a new process, the phenomenon in which the antireflection film is oxidized by water, the volume of the antireflection film expands, and the crack is generated in the passivation film.

### BRIEF DESCRIPTION OF THE DRAWINGS

FIG. 1 is a schematic plan view of an example of a semiconductor device according to a First Embodiment;

FIG. 2 is a schematic cross-sectional view of an example of the semiconductor device according to the First Embodiment;

FIG. 3 is a schematic enlarged cross-sectional view showing a region α in FIG. 2;

FIG. 4A is a schematic cross-sectional view showing an example of a manufacturing method of the semiconductor device according to the First Embodiment;

FIG. 4B is a schematic cross-sectional view showing an example of the manufacturing method of the semiconductor device according to the First Embodiment;

FIG. 4C is a schematic cross-sectional view showing an example of the manufacturing method of the semiconductor device according to the First Embodiment;

FIG. 4D is a schematic cross-sectional view showing an example of the manufacturing method of the semiconductor device according to the First Embodiment;

FIG. 5 is a schematic cross-sectional view of an example of a semiconductor device according to a Second Embodiment;

FIG. 6 is a schematic cross-sectional view of an example of a semiconductor device according to a Third Embodiment;

FIG. 7 is a schematic cross-sectional view of an example of a semiconductor device according to a Fourth Embodiment;

FIG. 8 is a schematic cross-sectional view of an example of a semiconductor device according to a Fifth Embodiment;

FIG. 9 is a schematic plan view of an example of a semiconductor device according to a Sixth Embodiment;

FIG. 10 is a schematic cross-sectional view of an example of the semiconductor device according to the Sixth Embodiment;

FIG. 11A is a schematic plan view of a modification of the semiconductor device according to the Sixth Embodiment;

FIG. 11B is a schematic plan view of a modification of the semiconductor device according to the Sixth Embodiment;

FIG. 11C is a schematic plan view of a modification of the semiconductor device according to the Sixth Embodiment;

FIG. 12A is a schematic plan view of another modification of the semiconductor device according to the Sixth Embodiment;

FIG. 12B is a schematic plan view of another modification of the semiconductor device according to the Sixth Embodiment;

FIG. 12C is a schematic plan view of another modification of the semiconductor device according to the Sixth Embodiment;

FIG. 13A is a schematic plan view of an example of a semiconductor device according to a Seventh Embodiment; and

FIG. 13B is a schematic cross-sectional view of an example of the semiconductor device according to the Seventh Embodiment.

### DETAILED DESCRIPTION

Hereinafter, a semiconductor device according to embodiments will be described with reference to the accompanying drawings.

### First Embodiment

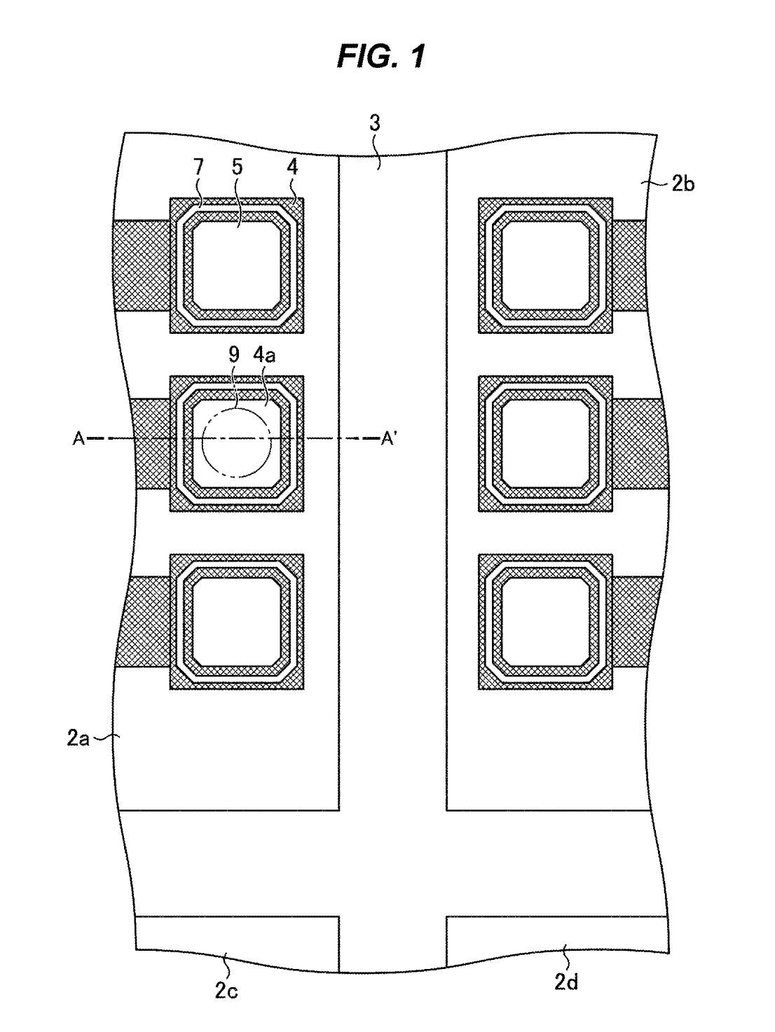

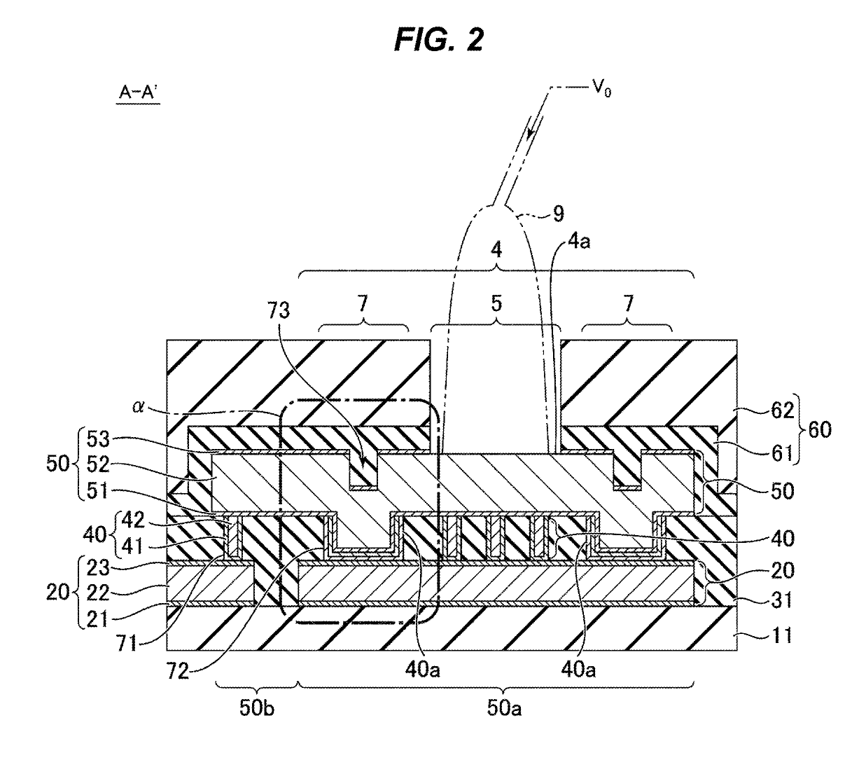

FIG. 1 is a schematic plan view of an example of a semiconductor device according to a First Embodiment. FIG. 2 is a schematic cross-sectional view of an example of the semiconductor device according to the First Embodiment. FIG. 2 shows a cross-section taken along a line AA′ in FIG. 1. A semiconductor chip 2a, which is a semiconductor device according to the embodiment, includes a pad aluminum wiring layer 50 which is a metal wiring layer and a passivation film 60 which is an insulating layer. The pad aluminum wiring layer 50 is used for a pad. The passivation film 60 is provided so as to cover the pad aluminum wiring layer 50, and has a pad opening portion 5 which is an opening portion from which a part of a surface of the pad aluminum wiring layer 50 is exposed. The pad aluminum wiring layer 50 includes a wiring metal 52 which is a first metal layer and an antireflection film 53 which is a second metal layer. The antireflection film 53 is provided over the wiring metal 52 except for the pad opening portion 5, and is thinner than the wiring metal 52 and has a reflectance lower than that of the wiring metal 52. The pad aluminum wiring layer 50 has a groove portion 7 in a predetermined region except for the pad opening portion 5. The wiring metal 52 protrudes, in an eaves shape, to the groove portion 7. The antireflection film 53 on the side wall inside the groove portion 7 is thinner than the antireflection film 53 outside the groove portion 7.

In the present embodiment, in the pad aluminum wiring layer 50 which is a metal wiring layer for a pad, the groove portion 7 is included in a predetermined region except for the pad opening portion 5 which is an opening portion for a pad. In addition, the wiring metal 52 which is the first metal layer protrudes, in an eaves shape, to a concave portion of the groove portion 7, and the antireflection film 53 which is the second metal layer over the side wall inside the concave portion of the groove portion 7 is thinner than the antireflection film 53 over a flat surface outside the groove portion 7. As a result, even if the antireflection film 53 is oxidized near the pad opening portion 5 and the oxidation reaches the groove portion 7, it is possible to prevent the oxidation beyond the groove portion 7. This is because the groove portion 7 exerts effects in which, since the antireflection film 53 is thin on the side wall inside the concave portion of the groove portion 7, the oxidation is suppressed, the volume expansion is very small even if the antireflection film 53 is oxidized, and the movement of oxygen or water is suppressed. Thereby, it is possible to prevent a phenomenon in which the antireflection film 53 is oxidized, the volume of the antireflection film 53 expands, and a crack is generated in the passivation film 60 which is an insulating layer over the pad aluminum wiring layer 50. That is, it is possible to prevent the quality degradation of the semiconductor chip 2a which is a semiconductor device.

Hereinafter, the semiconductor device according to the embodiment will be described in detail. FIG. 1 shows an example in which semiconductor chips 2a, 2b, 2c, and 2d which are semiconductor devices are provided over a semiconductor wafer via a dicing region 3. As to the semiconductor chips 2a, 2b, 2c, and 2d, a part of each chip is shown instead of the entire chip. As to the semiconductor chips 2a and 2b, bonding pads 4 of each chip are shown. Hereinafter, the semiconductor chips 2a, 2b, 2c, and 2d need not be distinguished from each other, and thus the semiconductor chip 2a will be described as a representative example.

The semiconductor chip 2a includes the bonding pad 4 and the passivation film (60). The passivation film (60) is provided so as to cover the bonding pad 4, and has the pad opening portion 5 from which a part of a surface of the bonding pad 4 is exposed. However, in FIG. 1, the passivation film (60) is omitted although the pad opening portion 5 is shown. Wiring such as a bonding wire 9 is coupled to (the pad aluminum wiring layer 50; described later, of) the bonding pad 4 exposed in the pad opening portion 5. The bonding wire 9 is coupled to a central region except for a peripheral region 4a of (the pad aluminum wiring layer 50 of) the bonding pad 4 exposed in the pad opening portion 5. The bonding pad 4 includes the groove portion 7. The groove portion 7 has a groove structure provided, in a ring shape, in (the pad aluminum wiring layer 50 of) the bonding pad 4 so as to surround the pad opening portion 5, and has a concave portion (recess) in a substrate direction.

FIG. 2 shows a portion higher than or equal to an interlayer insulating layer 11 positioned below a lower aluminum wiring layer 20 immediately below the pad aluminum wiring layer 50 of the bonding pad 4. Note that, for convenience of drawing, in FIG. 2, the size of the pad opening portion 5 is reduced and the entire diagram is enlarged in the film thickness direction.

The passivation film 60 includes a first passivation film 61 and a second passivation film 62. The first passivation film 61 is exemplified by a layered structure of silicon oxide (SiO₂) and silicon oxynitride (SiON). The second passivation film 62 is exemplified by polyimide.

The bonding pad 4 includes the lower aluminum wiring layer 20, vias 40, and the pad aluminum wiring layer 50. The lower aluminum wiring layer 20 is formed over the interlayer insulating layer 11. The interlayer insulating layer 11 is exemplified by silicon oxide (SiO₂). The lower aluminum wiring layer 20 has a layered structure including a barrier metal 21, a wiring metal 22, and an antireflection film 23. The barrier metal 21 is exemplified by titanium/titanium nitride (Ti/TiN), the wiring metal 22 is exemplified by an aluminum alloy (Al alloy), and the antireflection film 23 is exemplified by titanium nitride (TiN). An interlayer insulating layer 31 is formed over the lower aluminum wiring layer 20. The interlayer insulating layer 31 is exemplified by silicon oxide (SiO₂). The pad aluminum wiring layer 50 is formed over the interlayer insulating layer 31. The pad aluminum wiring layer 50 has a layered structure including a barrier metal 51, the wiring metal 52, and the antireflection film 53. The barrier metal 51 is exemplified by titanium/titanium nitride (Ti/TiN), the wiring metal 52 is exemplified by an aluminum alloy (Al alloy), and the antireflection film 53 is exemplified by titanium nitride (TiN). The via 40 is formed so as to penetrate through the interlayer insulating layer 31 and to couple between the lower aluminum wiring layer 20 and the pad aluminum wiring layer 50. The via 40 is formed by burying a via hole 71 that penetrates through the interlayer insulating layer 31, with a layered structure including a barrier metal 41 and a buried metal 42. The barrier metal 41 is exemplified by titanium nitride (TiN) and the buried metal 42 is exemplified by tungsten (W). The pad aluminum wiring layer 50 includes a pad portion 50a corresponding to a bonding pad main body and an extending portion 50b extending sideward from the pad portion 50a. The extending portion 50b couples to another lower aluminum wiring layer 20 via another via 40.

As described above, the groove portion 7 is provided in the pad aluminum wiring layer 50. In the groove portion 7, a via groove 72 that penetrates through the interlayer insulating layer 31 is imperfectly (partially) filled with a layered structure including the barrier metal 41 and the buried metal 42, and is further filled with a layered structure including the barrier metal 51, the wiring metal 52, and the antireflection film 53. Therefore, a via 40a (of the via groove 72) of the groove portion 7 is formed by a layered structure including the barrier metal 41, the buried metal 42, the barrier metal 51, the wiring metal 52, and the antireflection film 53. However, the via groove 72 need not be fully filled with the layered structure. A groove 73 is formed in an upper portion (above the via groove 72) of the groove portion 7. The position of the bottom surface of the groove 73 may be lower than the opening surface of the via groove 72.

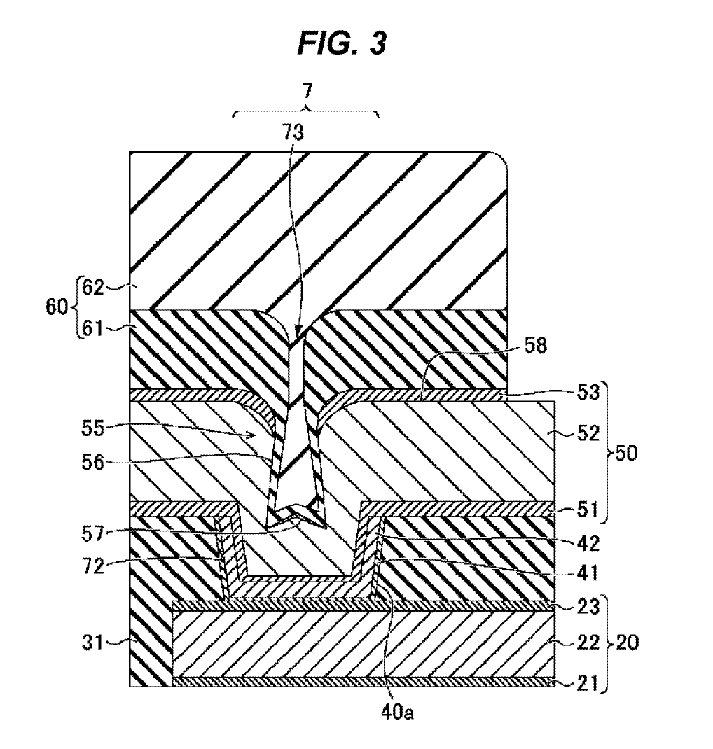

FIG. 3 is a schematic enlarged cross-sectional view showing a region α in FIG. 2. In the groove portion 7, the barrier metal 41 and the buried metal 42 are laminated on the side wall and the bottom surface of the via groove 72. However, different from the other vias 40, the width of the via 40a of the groove portion 7 is large. Therefore, the via groove 72 is not fully filled with the barrier metal 41 and the buried metal 42, and thus a groove (or a concave portion or a recess) remains. The barrier metal 51 and the wiring metal 52 are formed over the groove (or the concave portion or the recess). Therefore, the groove 73 is formed corresponding to the groove (or the concave portion or the recess) in an upper portion of the wiring metal 52. At this time, the wiring metal 52 has a shape protruding (overhanging), in an eaves shape, to the groove 73. That is, a portion of the wiring metal 52 (eaves portion 55) which hangs inside the groove portion 7 protrudes more to the center of the groove portion 7 than the inner side wall portion (inner wall portion 56) of the groove portion 7. Therefore, when viewing the groove 73 from above, the eaves portions 55 on both sides protrude toward the center of the groove 73, and thus a visible region in a bottom 57 is reduced. The antireflection film 53 is formed over the wiring metal 52. However, a portion of the wiring metal 52 shaded by the eaves portion 55, that is, the antireflection film 53 over the inner wall portion 56, is thinner than the antireflection film 53 on an outer portion 58 of the groove 73. It is preferable that the film thickness of at least a part of the antireflection film 53 on the inner wall portion 56 is zero. It is more preferable that the film thickness of the antireflection film 53 on the inner wall portion 56 is zero. However, in both cases, the antireflection film 53 may exist on the bottom 57.

As a result, even when the antireflection film 53 near the pad opening portion 5 is oxidized and the volume of the antireflection film 53 expands, the antireflection film 53 is extremely thin or absent in the groove portion 7, and thus the oxidation stops in the groove portion 7. As a result, the oxidation of the antireflection film 53 is limited to a very narrow range from the pad opening portion 5 to the groove portion 7 and the oxidation does not extend beyond the range. Thereby, it is possible to prevent a phenomenon in which the antireflection film 53 is widely oxidized and a crack is generated in the passivation film 60 over the pad aluminum wiring layer 50. Therefore, even if the titanium nitride (antireflection film 53) near the pad opening portion 5 is oxidized and the volume of the titanium nitride expands, it is possible to limit the oxidation and the volume expansion within an extremely narrow range by the groove portion 7. Thereby, it is possible to prevent a phenomenon in which the titanium nitride is widely oxidized and a crack is generated in the passivation film 60 over the aluminum alloy (pad aluminum wiring layer 50).

Note that at least a voltage V0 (≠0) is preferably intended to be applied to the bonding pad 4 from the bonding wire 9. This is because the antireflection film 53 in such a bonding pad 4 is more easily oxidized than that in a bonding pad 4 for grounding.

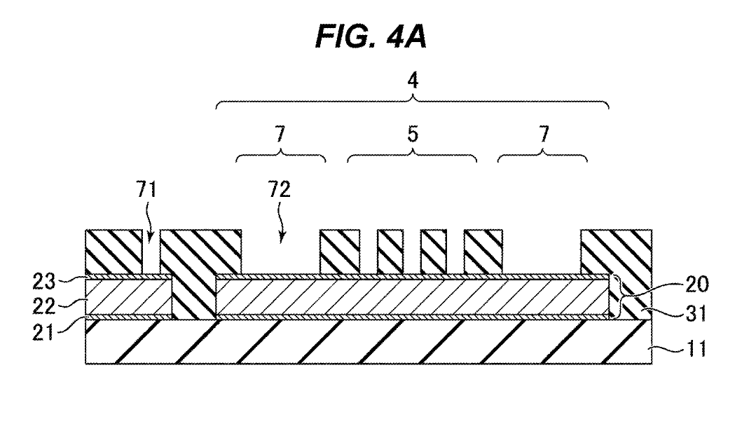

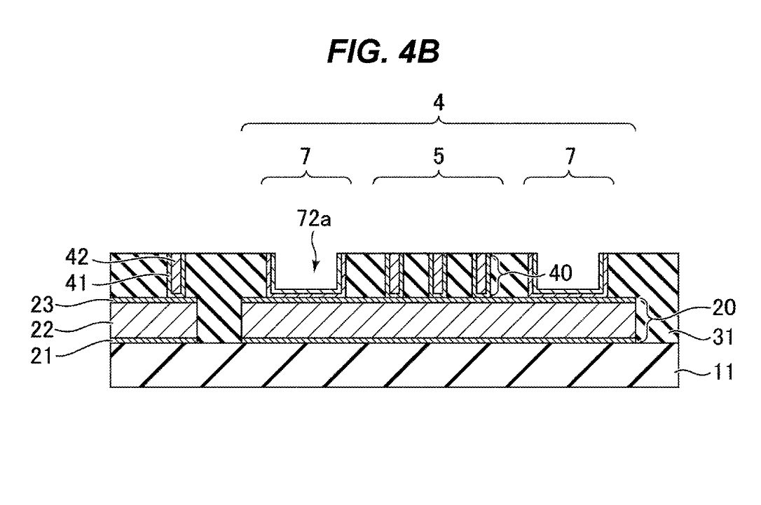

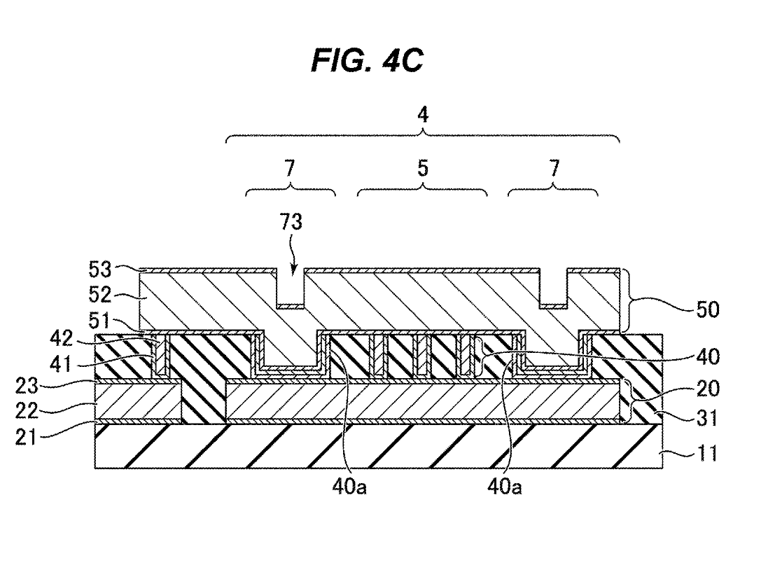

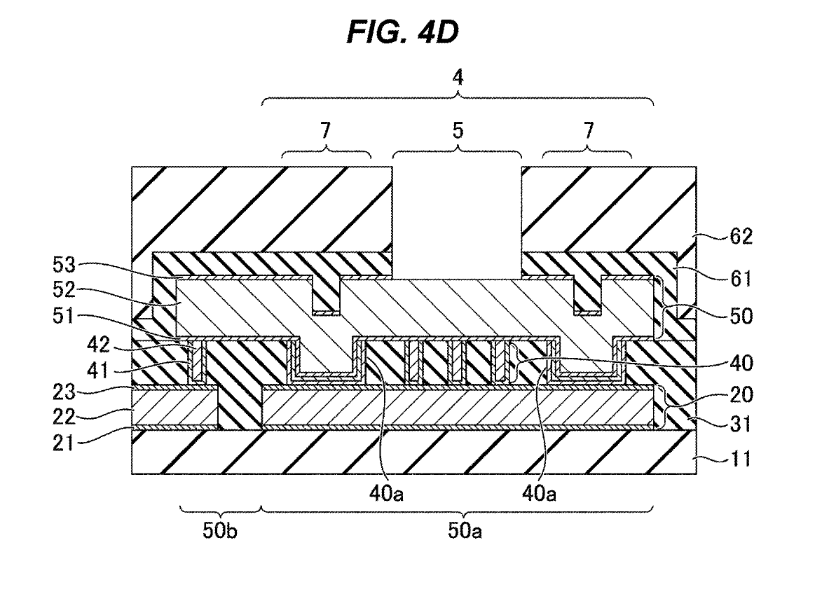

Next, a manufacturing method of the semiconductor device according to the First Embodiment will be described. FIGS. 4A to 4D are schematic cross-sectional views showing an example of the manufacturing method of the semiconductor device according to the First Embodiment. FIGS. 4A to 4D show a region where the bonding pad 4 is formed. However, the manufacturing method of the lower aluminum wiring layer 20 and layers below the lower aluminum wiring layer 20 is the same as a manufacturing method of a semiconductor device in related art, and thus the description thereof will be omitted.

The manufacturing method of the semiconductor device according to the present embodiment includes first to seventh processes. The first process is a process of forming the via hole 71 and the via groove 72 which is a groove, in the interlayer insulating layer 31 over the lower aluminum wiring layer 20 which is a lower wiring. The second process is a process of forming the buried metal 42 which is a metal layer so that the via hole 71 is filled and the via groove 72 is filled up to a half-way depth. The third process is a process of forming, by a sputtering method, the wiring metal 52 which is the first metal layer so as to cover the interlayer insulating layer 31 and the buried metal 42. The fourth process is a process of forming, by the sputtering method, the antireflection film 53 which is the second metal layer which is thinner than the wiring metal 52 and whose reflectance is lower than that of the wiring metal 52, so as to cover the wiring metal 52. The fifth process is a process of forming the bonding pad 4 which is a pad by etching the wiring metal 52 and the antireflection film 53. The sixth process is a process of forming the passivation film 60 which is an insulating layer so as to cover the bonding pad 4. The seventh process is a process of forming the pad opening portion 5 which is an opening portion by etching the passivation film 60 and the antireflection film 53 in a region except for a region including the via groove 72 so that a part of the surface of the wiring metal 52 in the boding pad 4 is exposed. The wiring metal 52 protrudes, in an eaves shape, to the via groove 72. The antireflection film 53 on the side wall inside the via groove 72 is thinner than the antireflection film 53 outside the via groove 72.

In the present embodiment, the via groove 72 is formed in a predetermined region except for a region of the pad opening portion 5 which is an opening portion for a pad. The via groove 72 is a groove which is not fully filled with the buried metal 42 which is a burying metal layer for the via, the wiring metal 52 which is the first metal layer for the pad wiring layer, and the antireflection film 53 which is the second metal layer for an antireflection film. Thereby, in a region of the via groove 72, a step is generated by a groove 72a after the buried metal 42 which is a burying metal layer for the via is formed and before the pad wiring layer is formed. Although the wiring metal 52 (exemplification: an aluminum alloy) for the pad wiring layer is formed by using the sputtering method, the groove 73 (a step) remains and the step forms a shape in which the wiring metal 52 protrudes (overhangs), in an eaves shape, inside the groove 73. Thereby, the antireflection film 53 (exemplification: titanium nitride) for an antireflection film which is formed by using the sputtering method becomes difficult to be formed on a portion shaded by the “eaves” in the shape in which the wiring metal 52 protrudes (overhangs) in an eaves shape, that is, the inner wall portion of the groove 73. As a result, the antireflection film 53 on the inner wall of the groove 73 is thinner than the antireflection film 53 outside the groove 73. Therefore, even if the antireflection film 53 is oxidized near the pad opening portion 5 and the oxidation reaches the groove 73, it is possible to prevent the oxidation beyond the groove 73. This is because the groove 73 exerts effects in which, since the antireflection film 53 is thin on the side wall inside the groove 73, the oxidation is suppressed, the volume expansion is small even if the antireflection film 53 is oxidized, and the movement of oxygen or water is suppressed. Thereby, it is possible to prevent a phenomenon in which the antireflection film 53 is oxidized, the volume of the antireflection film 53 expands, and a crack is generated in the passivation film 60 which is an insulating layer over the pad aluminum wiring layer 50 which is a metal wiring layer. In this case, it is possible to provide a region in which the antireflection film 53 for an antireflection film is thin (or removed), by not adding a new process but only partially changing the existing processes. As a result, it is possible to prevent the quality degradation of the semiconductor device.

Hereinafter, the manufacturing method of the semiconductor device according to the present embodiment will be described in detail. As shown in FIG. 4A, the interlayer insulating layer 31 is formed over the lower aluminum wiring layer 20 (exemplification: the barrier metal 21: titanium/titanium nitride, the wiring metal 22: an aluminum alloy, and the antireflection film 23: titanium nitride). Subsequently, the interlayer insulating layer 31 is planarized by using a CMP technique. Thereafter, the via holes 71 and the via groove 72 are formed in the interlayer insulating layer 31 at the same time by processes of lithography and etching. Here, the via groove 72 for forming the groove portion 7 will be described. While a normal via hole 71 is opened in a hole shape, the via groove 72 is opened in a groove shape so as to surround the pad opening portion 5 as shown in FIG. 1. Furthermore, the opening size (width) of the via groove 72 is greater than the opening size (a side or a diameter) of a normal via hole 71. For example, when a normal via hole 71 is opened into a hole shape with a size of 0.30 μm×0.30 μm, the via groove 72 is opened into a groove shape with a width of 2.0 μm.

Next, as shown in FIG. 4B, the barrier metal 41 is formed so as to cover the interlayer insulating layer 31, the via holes 71, and the via groove 72. Subsequently, the buried metal 42 is formed so as to cover the barrier metal 41. Thereafter, planarization is performed by using a CMP technique, and thus the barrier metal 41 and the buried metal 42 over the interlayer insulating layer 31 are removed. Thereby, the normal via holes 71 are filled with the barrier metal 41 and the buried metal 42, and thus the vias 40 are formed. At this time, the via groove 72 is not filled with the barrier metal 41 and the buried metal 42, and thus the groove 72a (a step) remains. As the barrier metal 41, for example, a titanium nitride film with a thickness of 50 nm is formed. As the buried metal 42, for example, a tungsten film with a thickness of 200 nm is formed. As a result, when the thickness of the interlayer insulating layer 31 over the lower aluminum wiring layer 20 is, for example, 1.0 μm, the via groove 72 is not fully filled with the buried metal 42, and thus the groove 72a with a step of 750 nm is formed.

Subsequently, as shown in FIG. 4C, the barrier metal 51 is formed by the sputtering method so as to cover the interlayer insulating layer 31, the barrier metal 41, and the buried metal 42. As the barrier metal 51, for example, a laminated film of a titanium film with a thickness of 30 nm and a titanium nitride film with a thickness of 40 nm is formed. Next, the wiring metal 52 is formed by the sputtering method so as to cover the barrier metal 51. As the wiring metal 52, for example, an aluminum alloy film with a thickness of 1.6 μm is formed. At this time, in an upper portion of the wiring metal 52, the groove 73 is formed corresponding to the groove 72a (the step) in the via groove 72. In addition, the wiring metal 52 has a shape protruding (overhanging), in an eaves shape, inside the groove 73. Subsequently, the antireflection film 53 is formed by the sputtering method so as to cover the wiring metal 52. As the antireflection film 53, for example, a titanium nitride film with a thickness of 30 nm is formed. At this time, the antireflection film 53 is difficult to be formed on a portion shaded by the eaves in the shape in which the wiring metal 52 protrudes (overhangs) in an eaves shape, that is, the inner wall portion of the groove 73. As a result, the film thickness of the antireflection film 53 on the inner wall portion of the groove 73 is thinner than that of the antireflection film 53 outside the groove 73, or the film thickness is zero. Thereafter, the pad aluminum wiring layer 50 formed by the layered structure of the barrier metal 51, the wiring metal 52, and the antireflection film 53 is patterned into a shape of the bonding pad 4 by processes of lithography and etching. At this stage, the via groove 72 is filled with the barrier metal 41, the buried metal 42, the barrier metal 51, the wiring metal 52, and the antireflection film 53. As a result, the via 40a is substantially formed. However, when the via groove 72 is deep, the via groove 72 may not be fully filled up, and thus the groove 73 may be lower than the upper surface of the interlayer insulating layer 31.

Thereafter, as shown in FIG. 4D, the first passivation film 61 and the second passivation film 62 are formed. As the first passivation film 61, for example, a layered structure of a silicon oxide film with a thickness of 100 nm and a silicon oxynitride film with a thickness of 1000 nm is formed. As the second passivation film 62, for example, positive-type photosensitive polyimide is used and is applied with a film thickness of 10 μm. Subsequently, in the positive-type photosensitive polyimide, the position of the pad opening portion 5 is exposed and then developed, and thus the exposed portion is removed. Thereafter, the pad opening portion 5 (exemplification: a substantially rectangular shape with a side length of 70 μm) is formed by the removal of the first passivation film 61 and the antireflection film 53 of the pad aluminum wiring layer 50 by dry etching through the use of the second passivation film 62 as a mask. After that, the bonding wire 9 (exemplification: a diameter of about 50 μm) is coupled.

As described above, the semiconductor device is manufactured.

When comparing the above manufacturing method with an existing manufacturing method, the modification is that the via groove 72 is formed at the same time, in the process of manufacturing the normal via holes 71. That is, the mask of the via holes 71 is partially changed, and thus the via groove 72 can also be formed. In this way, only a part of an existing process is changed and it is not necessary to add a new process.

It is possible to achieve the formation of the wiring metal 52 into a shape which protrudes (overhangs) in an eaves shape by adjusting the width and the depth of the via groove 72. For example, when the width is too wide, a film forming component coming from the side increases, and thus the overhang shape is not formed. The width needs to be greater than the width of, for example, the via hole 71. The width may be smaller than twice the film thickness of the wiring metal 52 in the outer portion 58 of the groove portion 7. In addition, it is also possible to realize the shape by adjusting sputtering conditions.

In the present embodiment, the barrier metal 51, the wiring metal 52, and the antireflection film 53 in the pad aluminum wiring layer 50 are formed by the sputtering method. Here, the sputtering method is a film forming method in which ions are caused to collide with a metal target and atoms scattered from the surface of the target reach a substrate to form a film. The amount of formed film depends on the size of the view angle of the target as seen from the portion where the film is formed. That is, the film formation by the sputtering method has characteristics in which the film can be uniformly formed on a flat region, but the amount of formed film tends to be small on a side surface portion when there is a step. Therefore, for example, when forming a film of an aluminum alloy (the wiring metal 52) of 1.6 μm on the groove 72a with a step (depth) of 750 nm and a width of 1.5 μm by the sputtering method, the aluminum alloy after the film forming has an overhang shape. This is because it becomes difficult for film forming particles to penetrate inside the groove 72a while the film is being formed from the above-mentioned characteristics of the sputtering method, and thus the film thickness is thin on the side wall portion inside the groove 72a.

Although a titanium nitride film (the antireflection film 53) is formed over the aluminum alloy film by the sputtering method, the titanium nitride film is not formed or becomes very thin, on a portion shaded by the eaves of the overhang shape. This is also because it becomes difficult for film forming particles to penetrate a region shaded by the eaves inside the groove 73 while the film is being formed from the above-mentioned characteristics of the sputtering method, and thus the film is difficult to be formed on the side wall portion inside the groove 73. As a result, the via groove 72 with appropriate width and depth is formed around a region serving as the pad opening portion 5, and thus it is possible to create a portion where the titanium nitride film (the antireflection film 53) is very thin or is not formed. Thereby, even if the titanium nitride exposed between the first passivation film 61 and the aluminum alloy is oxidized around the pad opening portion 5, it becomes possible to limit the oxidized region to a region up to the groove portion 7. As a result, it is possible to prevent cracking in the passivation film by the oxidation of the titanium nitride by changing only a part of an existing process such as forming the via groove 72 and the normal via holes 71 at the same time and by not adding a new process. At this time, the adjustment of the type and thickness of the passivation film makes it possible to further suppress cracking in the passivation film by the oxidation of the titanium nitride.

### Second Embodiment

A semiconductor device according to a Second Embodiment will be described. The present embodiment is different from the First Embodiment in that the lower aluminum wiring layer 20 below the via groove 72 (groove portion 7) is removed and the depth of the via groove 72 (groove portion 7) is increased. In other words, the lower aluminum wiring layer 20 below the via groove 72 (groove portion 7) is removed in order to deepen the via groove 72 (groove portion 7). Hereinafter, the difference from the First Embodiment will be mainly described.

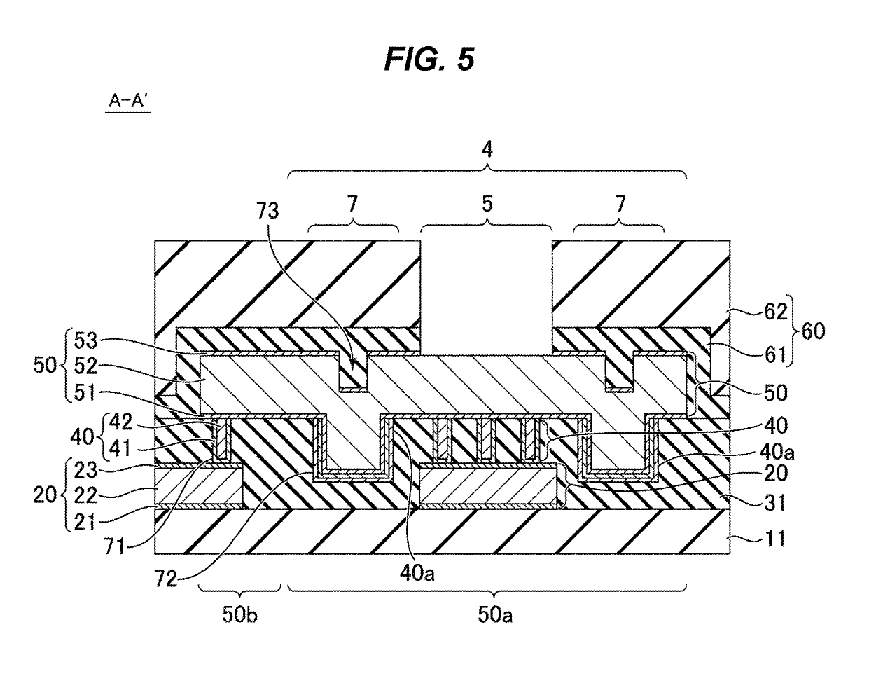

FIG. 5 is a schematic cross-sectional view of an example of the semiconductor device according to the Second Embodiment. FIG. 5 also shows a cross-section taken along the line AA′ in FIG. 1 and shows a portion higher than or equal to the interlayer insulating layer 11 positioned below the lower aluminum wiring layer 20 immediately below the pad aluminum wiring layer 50 of the bonding pad 4. Note that, for convenience of drawing, in FIG. 5, the size of the pad opening portion 5 is reduced and the entire diagram is enlarged in the film thickness direction. Moreover, the description of the bonding wire 9 is omitted.

In the semiconductor device according to the First Embodiment shown in the above-mentioned FIG. 2, the lower aluminum wiring layer 20 is arranged below the via groove 72 (groove portion 7), and the lower aluminum wiring layer 20 functions as a stopper of the etching of the via 40. However, in the semiconductor device according to the present embodiment shown in FIG. 5, the lower aluminum wiring layer 20 is not arranged below the via groove 72 (groove portion 7) and the etching of the via 40a reaches about half the height of the lower aluminum wiring layer 20. That is, the via 40a is thicker (deeper) than the via 40.

For example, when the film thickness of the interlayer insulating layer 31 between the pad aluminum wiring layer 50 and the lower aluminum wiring layer 20 is thin, the step of the via groove 72 before the formation of the pad aluminum wiring layer 50, is insufficient, and thus there is a risk that the shape of the aluminum alloy which is the wiring metal 52 is not an overhang shape. In this case, it does not become possible to create a region in which the titanium nitride film which is the antireflection film 53 is very thin or not formed. In order to avoid the above situation, it is considered that the lower aluminum wiring layer 20 below the via groove 72 may be removed and the depth of the via groove 72 may be larger than the position of the upper surface of the lower aluminum wiring layer 20. That is, the depth of the via groove 72 is made larger. Thereby, the shape of the aluminum alloy which is the wiring metal 52 can be a desired overhang shape, and thus it becomes possible to create a region in which the titanium nitride film which is the antireflection film 53 is very thin or is not formed.

As a manufacturing method realizing the above structure, first, in the process of forming the lower aluminum wiring layer, the shape of the lower aluminum wiring layer 20 is partially changed and the lower aluminum wiring layer 20 is etched into a shape in which the lower aluminum wiring layer 20 is not arranged below the via groove 72. The etching time is increased in a process of etching the via holes 71 and the via groove 72. Thereby, while the etching of the via holes 71 stops at the lower aluminum wiring layer 20, the etching of the via groove 72 continues, and thus the via groove 72 can be deeper than the via holes 71.

When comparing this manufacturing method with an existing manufacturing method, there exist differences described below. The first difference is that, in the process of etching the normal lower aluminum wiring layer 20 into a desired shape, the shape of the lower aluminum wiring layer 20 is partially changed. That is, by partially changing a mask of the lower aluminum wiring layer 20, the shape of the lower aluminum wiring layer 20 is changed. The second difference is that, in the process of manufacturing the normal via holes 71, the via groove 72 is formed at the same time. That is, the mask of the via holes 71 is partially changed, and thus the via groove 72 can also be formed. The third difference is that, in the process of manufacturing the normal via holes 71, the etching time is a little increased. These differences can be realized by only changing a part of the existing processes, and it is not necessary to add a new process.

Also in this case, the same effects as those of the First Embodiment can be obtained. In addition, even when the film thickness of the interlayer insulating layer between the pad aluminum wiring layer and the lower aluminum wiring layer is thin, it is possible to form desired via groove and groove portion.

### Third Embodiment

A semiconductor device according to a Third Embodiment will be described. The present embodiment is different from the First Embodiment in that the pad aluminum wiring layer 50 and the lower aluminum wiring layer 20 are coupled by a via 40b using the wiring metal 52 instead of the via 40 using the buried metal 42. In other words, the via is thickened and the process of forming the buried metal 42 is eliminated. Hereinafter, the difference from the First Embodiment will be mainly described.

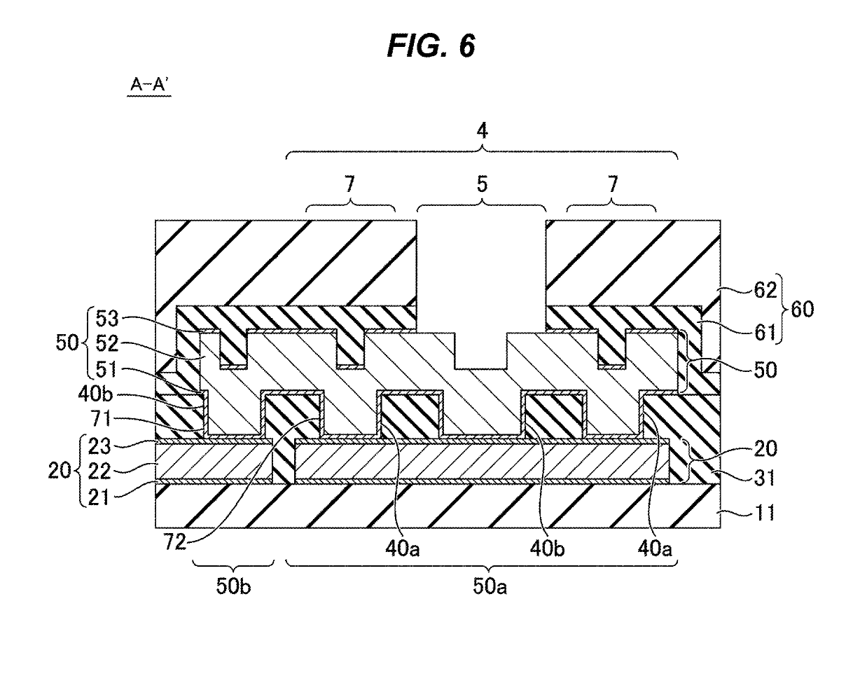

FIG. 6 is a schematic cross-sectional view of an example of the semiconductor device according to the Third Embodiment. FIG. 6 also shows a cross-section taken along the line AA′ in FIG. 1 and shows a portion higher than or equal to the interlayer insulating layer 11 positioned below the lower aluminum wiring layer 20 immediately below the pad aluminum wiring layer 50 of the bonding pad 4. Note that, for convenience of drawing, in FIG. 6, the size of the pad opening portion 5 is reduced and the entire diagram is enlarged in the film thickness direction. In addition, the description of the bonding wire 9 is omitted.

In the semiconductor device according to the First Embodiment shown in the above-mentioned FIG. 2, the buried metal 42 such as tungsten is used for the via 40 that couples the lower aluminum wiring layer 20 to the pad aluminum wiring layer 50. However, the via used as an internal wiring has a large size such as, for example, 2.5 μm×2.5 μm, and thus the via need not be filled with the buried metal 42 if there is no problem as to the conductivity and the quality even when the buried metal 42 is not used. In the semiconductor device according to the present embodiment shown in FIG. 6, the via 40b using the wiring metal 52 is used as the via that couples the lower aluminum wiring layer 20 to the pad aluminum wiring layer 50. Thereby, both the barrier metal 41 and the buried metal 42 are absent on the bottom of the via groove 72, and thus the depth (step) of the via groove 72 can be large. Thereby, the shape of the aluminum alloy which is the wiring metal 52 can more easily be a desired overhang shape, and thus it is possible to create a region in which the titanium nitride film which is the antireflection film 53 is very thin or is not formed.

As a manufacturing method realizing the above structure, first, in the process of etching the via holes 71 and the via groove 72, the normal via holes 71 are opened, in a large size, along with the via groove 72. In addition, the processes of forming the barrier metal 41 and the buried metal 42 and the CMP process are omitted.

When comparing this manufacturing method with an existing manufacturing method, there are differences described below. The first difference is that, in the process of manufacturing the normal via holes 71, the size of the via holes 71 is increased and the via groove 72 is formed at the same time. That is, the mask of the via holes 71 is partially changed, and thus the size of the via holes 71 is changed and the via groove 72 can also be formed. The second difference is that the processes of forming the barrier metal 41 and the buried metal 42 and the CMP process are omitted. These differences can be realized by only changing a part of the existing processes, and it is not necessary to add a new process.

Also in this case, the same effects as those of the First Embodiment can be obtained. In addition, the step (depth) of the via groove 72 for forming the wiring metal 52 can be large. Note that the present embodiment can also be applied to a case where the film thickness of the interlayer insulating layer between the pad aluminum wiring layer and the lower aluminum wiring layer is thin.

### Fourth Embodiment

A semiconductor device according to a Fourth Embodiment will be described. The present embodiment is different from the First Embodiment in that the groove portion 7 (via 40a) not only creates a region in which the titanium nitride film which is the antireflection film 53 is very thin or not formed, but also has a function to couple to a lower layer wiring that connects to an internal circuit. Hereinafter, the difference from the First Embodiment will be mainly described.

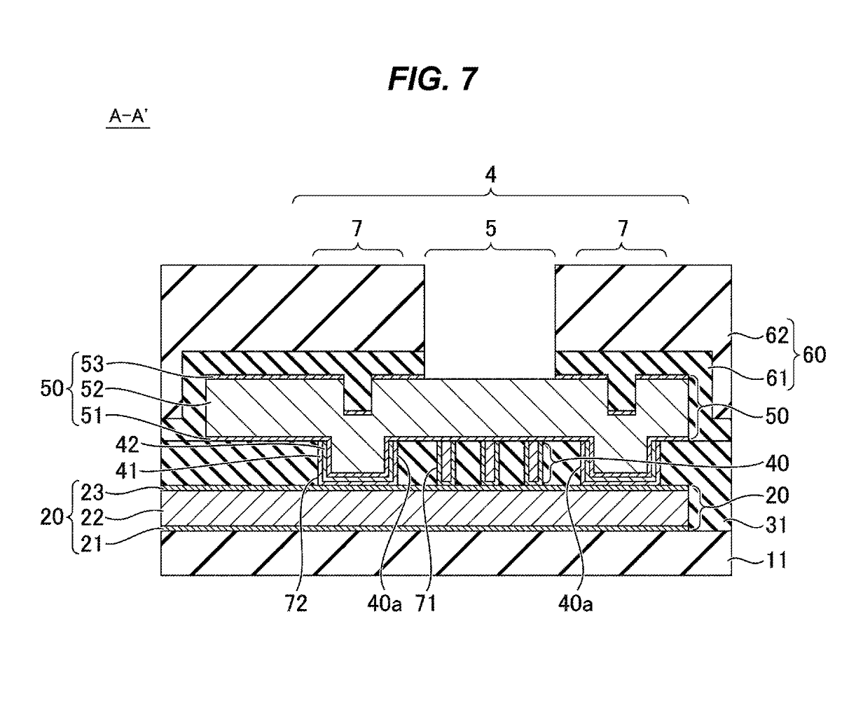

FIG. 7 is a schematic cross-sectional view of an example of the semiconductor device according to the Fourth Embodiment. FIG. 7 also shows a cross-section taken along the line AA′ in FIG. 1 and shows a portion higher than or equal to the interlayer insulating layer 11 positioned below the lower aluminum wiring layer 20 immediately below the pad aluminum wiring layer 50 of the bonding pad 4. Note that, for convenience of drawing, in FIG. 7, the size of the pad opening portion 5 is reduced and the entire diagram is enlarged in the film thickness direction. In addition, the description of the bonding wire 9 is omitted.

In the semiconductor device according to the First Embodiment shown in the above-described FIG. 2, the groove portion 7 (via 40a) has only a function to create a region in which the titanium nitride film which is the antireflection film 53 is very thin or is not formed, and the function to couple to the lower aluminum wiring layer 20 that connects to an internal circuit is played by another normal via 40. However, the groove portion 7 (via 40a) may have the function to couple to the lower aluminum wiring layer 20 that connects to the internal circuit. In the semiconductor device according to the present embodiment shown in FIG. 7, the groove portion 7 (via 40a) plays not only the function to create a region in which the titanium nitride film which is the antireflection film 53 is very thin or not formed, but also the function to couple to the lower aluminum wiring layer 20 that connects to the internal circuit. With the configuration as described above, it is possible to reduce the size of the semiconductor device by the size of a region in which the normal via 40 couples to the lower aluminum wiring layer 20 that connects to the internal circuit (exemplification: by the size of the extending portion 50b in FIG. 2). Thereby, it is possible to contribute to manufacturing a low-cost semiconductor device.

When comparing the above manufacturing method with an existing manufacturing method, the modification is that, in the process of manufacturing the normal via holes 71, the number of the via holes 71 is reduced and the via groove 72 is formed at the same time. That is, the mask of the via holes 71 is partially changed, and thus the number of the via holes 71 is reduced and the via groove 72 can also be formed. In this way, only a part of existing processes is changed and it is not necessary to add a new process.

Also in this case, the same effects as those of the First Embodiment can be obtained. In addition, the area of the semiconductor device can be reduced and the semiconductor device can be manufactured at low cost.

### Fifth Embodiment

A semiconductor device according to a Fifth Embodiment will be described. The present embodiment is different from the First Embodiment in that copper is used as the lower wiring layer. Hereinafter, the difference from the First Embodiment will be mainly described.

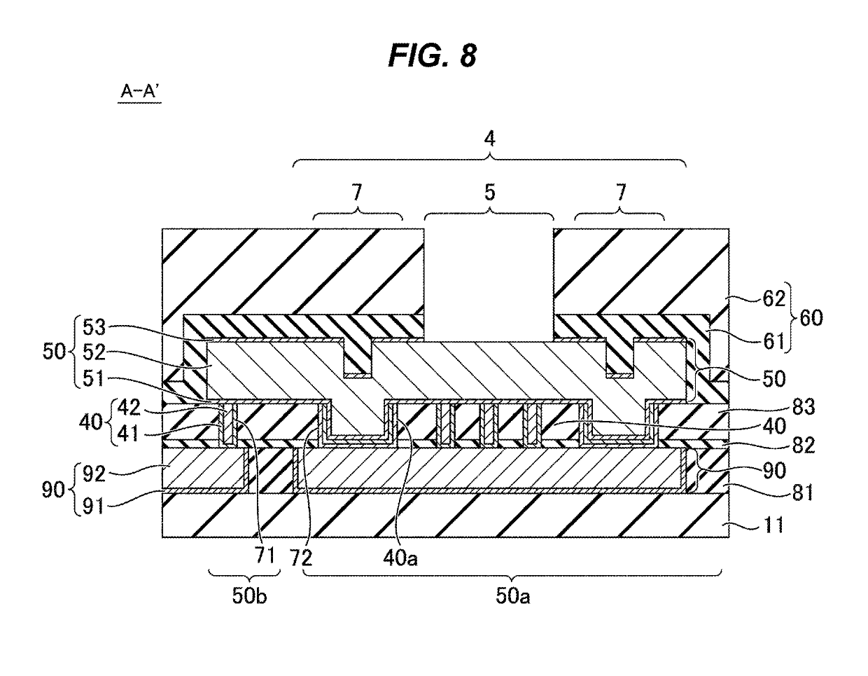

FIG. 8 is a schematic cross-sectional view of an example of the semiconductor device according to the Fifth Embodiment. FIG. 8 also shows a cross-section taken along the line AA′ in FIG. 1 and shows a portion higher than or equal to the interlayer insulating layer 11 positioned below the lower aluminum wiring layer 20 immediately below the pad aluminum wiring layer 50 of the bonding pad 4. Note that, for convenience of drawing, in FIG. 8, the size of the pad opening portion 5 is reduced and the entire diagram is enlarged in the film thickness direction. Furthermore, the description of the bonding wire 9 is omitted.

In the semiconductor device according to the First Embodiment shown in the above-mentioned FIG. 2, the lower aluminum wiring layer 20 including the wiring metal 22 of an aluminum alloy is used as the lower wiring layer. However, copper may be used as the lower wiring layer. In the semiconductor device according to the present embodiment shown in FIG. 8, a lower copper wiring layer 90 including a wiring metal 92 of copper (Cu) is used as the lower wiring layer. The lower copper wiring layer 90 includes a barrier metal 91 including tantalum/tantalum nitride (Ta/TaN) and a wiring metal 92 including copper (Cu). Note that interlayer insulating layers 81, 82, and 83 are exemplified by a silicon oxide film (SiO₂), a silicon nitride film (SiNx), and a silicon oxide film (SiO₂), respectively. In addition, it is also possible to apply such copper wiring to the Second Embodiment to the Fourth Embodiment.

The comparison between this manufacturing method and an existing manufacturing method is the same as that in the First Embodiment.

Also in this case, the same effects as those of the First Embodiment can be obtained. In addition, it is possible to apply the Second Embodiment to the Fourth Embodiment not only to the semiconductor device whose lower wiring layer is aluminum wiring, but also to the semiconductor device whose lower wiring layer is copper wiring, and thus the Second Embodiment to the Fourth Embodiment can be applied to many semiconductor devices.

### Sixth Embodiment

A semiconductor device according to a Sixth Embodiment will be described. The present embodiment is different from the First Embodiment in that the groove portion 7 does not surround the pad opening portion 5. Hereinafter, the difference from the First Embodiment will be mainly described.

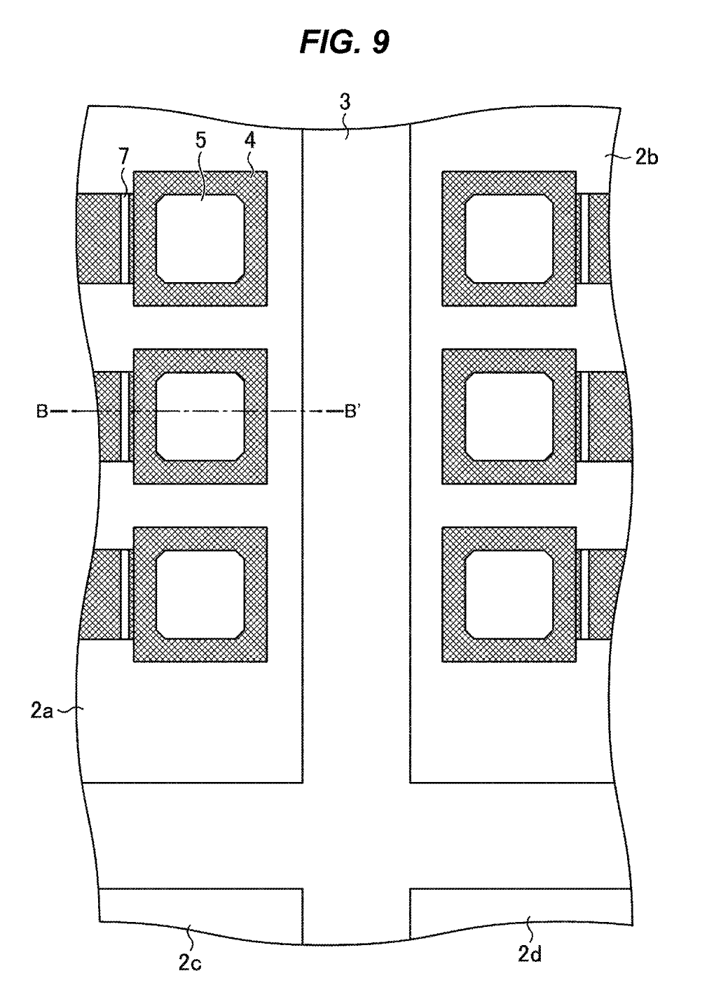

FIG. 9 is a schematic plan view of an example of the semiconductor device according to the Sixth Embodiment. In the same manner as in FIG. 1, FIG. 9 also shows an example in which there are provided the semiconductor chips 2a, 2b, 2c, and 2d which are semiconductor devices over a semiconductor wafer via the dicing region 3. Then, as to the semiconductor chips 2a, 2b, 2c, and 2d, a part of these chips is shown instead of the whole of these chips. As to the semiconductor chips 2a and 2b, the bonding pads 4 of each chip are shown. Hereinafter, the semiconductor chips 2a, 2b, 2c, and 2d need not be distinguished from each other, and thus the semiconductor chip 2a will be described as a representative example.

In the semiconductor device according to the First Embodiment shown in the above-mentioned FIG. 1, the groove portion 7 is arranged so as to surround the pad opening portion 5. However, for example, in a semiconductor device using narrow pitch bonding pads, it is necessary to significantly reduce the size of (narrow) the pad opening portion 5 in order to arrange the groove portion 7 so as to surround the pad opening portion 5. In that case, there is a possibility that the probing performance at the time of testing the semiconductor device is degraded and the bonding performance at the time of assembling the semiconductor device into a package is degraded. Therefore, the configuration in which the groove portion 7 is arranged as shown in FIG. 1 may not necessarily be appropriate for a semiconductor device having narrow pitch bonding pads.

However, in the semiconductor device according to the present embodiment, the groove portion 7 is not arranged so as to surround the pad opening portion 5. In the semiconductor device according to the present embodiment, the groove portion 7 is arranged only in an leader wiring portion in a coupling portion between a main body portion and the leader wiring portion of the bonding pad 4, along the width direction of the leader wiring portion. At this time, the groove portion 7 is arranged so that one end of the groove portion 7 reaches one end in the width direction of the leader wiring portion of the bonding pad 4 and the other end of the groove portion 7 reaches the other end in the width direction of the leader wiring portion of the bonding pad 4. In addition, the description of the bonding wire 9 is omitted.

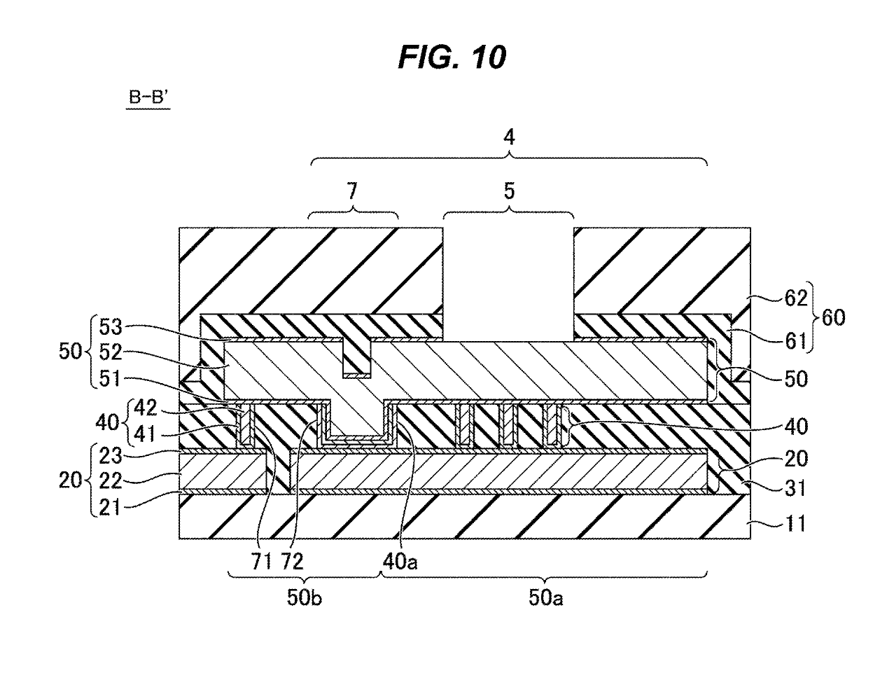

FIG. 10 is a schematic cross-sectional view of an example of the semiconductor device according to the Fifth Embodiment. FIG. 10 shows a cross-section taken along the line BB′ in FIG. 9 and shows a portion higher than or equal to the interlayer insulating layer 11 positioned below the lower aluminum wiring layer 20 immediately below the pad aluminum wiring layer 50 of the bonding pad 4. Note that, for convenience of drawing, in FIG. 10, the size of the pad opening portion 5 is reduced and the entire diagram is enlarged in the film thickness direction.

The groove portion 7 is arranged in the extending portion 50b in a coupling portion between the pad portion 50a in the pad aluminum wiring layer 50 corresponding to the main body portion of the bonding pad 4 and the extending portion 50b corresponding to the leader wiring portion. In this way, by the arrangement of the groove portion 7 in the extending portion 50b, it is possible to open the pad opening portion 5 of a conventional size. In this case, there is considered a case where, in the pad opening portion 5, the titanium nitride of the antireflection film 53 which is exposed between the passivation film 60 and the wiring metal 52 is oxidized and all the titanium nitride on the upper surface of the pad portion 50a is oxidized. However, even in that case, the oxidation phenomenon is contained in that range, and thus the oxidation phenomenon is not generated in a range of the extending portion 50b beyond the groove portion 7. Therefore, the region where the oxidation phenomenon is generated is limited to an extremely narrow range, and thus even when the titanium nitride is oxidized and the volume of the titanium nitride expands, it can be considered that the volume does not expand enough to generate a crack in the passivation film 60. Thereby, even in the semiconductor device having narrow pitch bonding pads 4, it is possible to prevent a crack in the passivation film 60, which is caused by the oxidation phenomenon of the titanium nitride of the antireflection film 53.

In other words, it can be said that the groove portion 7 may be arranged so that the region where the oxidation phenomenon is generated is limited to an extremely narrow range. Therefore, when the pad aluminum wiring layer 50 (layer including the antireflection film 53) of the bonding pad 4 has a shape asymmetrical with respect to the pad opening portion 5, it is considered that the oxidation can be prevented if the groove portion 7 is provided on the side where the area of the pad aluminum wiring layer 50 is large with respect to the pad opening portion 5. Thereby, it is possible to prevent the oxidation on the side where the area is large, and thus the crack can be effectively prevented. In the case of FIG. 9, the pad aluminum wiring layer 50 (layer including the antireflection film 53) has a shape which extends long on the side of the extending portion 50b (the leader wiring portion) and which is asymmetrical with respect to the pad opening portion 5. Therefore, the groove portion 7 may be provided on the side of the extending portion 50b (the leader wiring portion) with respect to the pad opening portion 5. Accordingly, in the case of FIG. 9, the groove portion 7 is provided in the coupling portion between the leader wiring portion and the main body portion. In addition, from the viewpoint of prevention of oxidation, it can be said that the groove portion 7 may be not only a groove, but also a concave portion, a recess, and a step.

The comparison between this manufacturing method and an existing manufacturing method is the same as that in the First Embodiment.

Also in this case, the same effects as those of the First Embodiment can be obtained. In addition, the present embodiment can be applied also to the Second Embodiment to the Fifth Embodiment, and thus the present embodiment can be applied to many semiconductor devices.

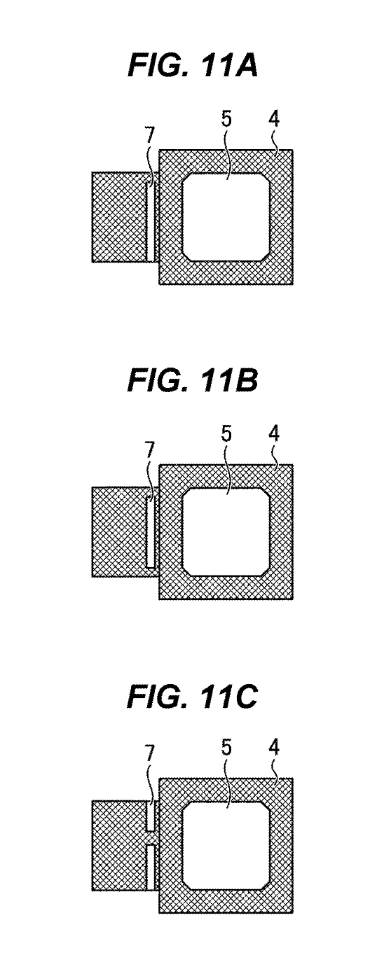

Next, a modification of the semiconductor device according to the Sixth Embodiment will be described. FIGS. 11A to 11C are schematic plan views of the modification of the semiconductor device according to the Sixth Embodiment. Also in FIG. 11A, the groove portion 7 is arranged only in the leader wiring portion in the coupling portion between the main body portion and the leader wiring portion of the bonding pad 4, along the width direction of the leader wiring portion. However, in the case of FIG. 11A, one end of the groove portion 7 reaches one end of the leader wiring portion of the bonding pad 4, in the width direction of the leader wiring portion. In addition, the other end of the groove portion 7 does not reach the other end of the leader wiring portion of the bonding pad 4 in the width direction of the leader wiring portion, although the other end of the groove portion 7 is located near the other end of the leader wiring portion. In this way, even if there is a slight portion where the groove portion 7 is absent in the leader wiring portion in the width direction, the groove portion is present in most of the other portion, and thus the effect of suppressing oxidation can be exerted.

Similarly, also in FIG. 11B, the groove portion 7 is arranged only in the leader wiring portion in the coupling portion between the main body portion and the leader wiring portion of the bonding pad 4, along the width direction of the leader wiring portion. However, in the case of FIG. 11B, one end of the groove portion 7 does not reach one end of the leader wiring portion of the bonding pad 4 in the width direction of the leader wiring portion, although the one end of the groove portion 7 is located near the one end of the leader wiring portion. Moreover, the other end of the groove portion 7 does not reach the other end of the leader wiring portion of the bonding pad 4 in the width direction of the leader wiring portion, although the other end of the groove portion 7 is located near the other end of the leader wiring portion. In this way, even if there is a slight portion where the groove portion 7 is absent in the leader wiring portion in the width direction, the groove portion is present in most of the other portion, and thus the effect of suppressing oxidation can be exerted.

Similarly, also in FIG. 11C, the groove portion 7 is arranged only in the leader wiring portion in the coupling portion between the main body portion and the leader wiring portion of the bonding pad 4, along the width direction of the leader wiring portion. However, in the case of FIG. 11C, the groove portion 7 is partially disconnected in the middle of the groove portion 7. In this way, even if there is a slight portion where the groove portion 7 is absent in the leader wiring portion in the width direction, the groove portion is present in most of the other portion, and thus the effect of suppressing oxidation can be exerted.

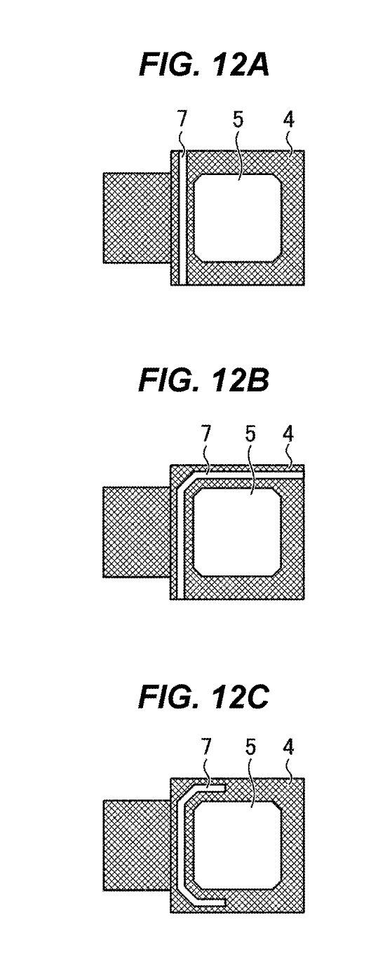

FIGS. 12A to 12C are schematic plan views of other modifications of the semiconductor device according to the Sixth Embodiment. Also in FIG. 12A, the groove portion 7 is not arranged so as to surround the pad opening portion 5. In the case of FIG. 12A, the groove portion 7 is arranged only in the main body portion in the coupling portion between the main body portion and the leader wiring portion of the bonding pad 4, along the width direction of the main body portion. At this time, the groove portion 7 is arranged so that one end of the groove portion 7 reaches one end of the main body portion of the bonding pad 4 and the other end reaches the other (opposing) end of the main body portion of the bonding pad 4. This case is also substantially the same as the case of FIG. 9, and thus the same effects can be exerted. Note that, in this case, there may be a slight portion where the groove portion 7 is absent as in FIGS. 11A to 11C.

Also in FIG. 12B, the groove portion 7 is not arranged so as to surround the pad opening portion 5. In the case of FIG. 12B, the groove portion 7 is arranged so as to partially surround the pad opening portion 5. Specifically, there is arranged the groove portion 7 which is right-angled along two sides perpendicular to each other of the main body portion (pad portion 50a) of the bonding pad 4. Both ends of the groove portion 7 reach ends of the main body portion of the bonding pad 4. This case is also substantially the same as the case of FIG. 9, and thus the same effects can be exerted. Note that, in this case, there may be a slight portion where the groove portion 7 is absent as in FIGS. 11A to 11C.

Also in FIG. 12C, the groove portion 7 is not arranged so as to surround the pad opening portion 5. In the case of FIG. 12C, the groove portion 7 is arranged so as to partially surround the pad opening portion 5. Specifically, as compared with the case of FIG. 1, there is arranged about a half groove portion 7 on the side of the leader wiring portion (extending portion 50b), in the bonding pad 4. In this way, even if there is a portion where the groove portion 7 is absent in the main body portion of the bonding pad 4, the groove portion is present in most of the other portion, and thus the effect of preventing oxidation can be exerted.

### Seventh Embodiment

A semiconductor device according to a Seventh Embodiment will be described. The present embodiment is different from the First Embodiment in that the bonding wire 9 is provided on the entire surface of (the pad aluminum wiring layer of) the bonding pad 4 exposed to the pad opening portion 5. Hereinafter, the difference from the First Embodiment will be mainly described.

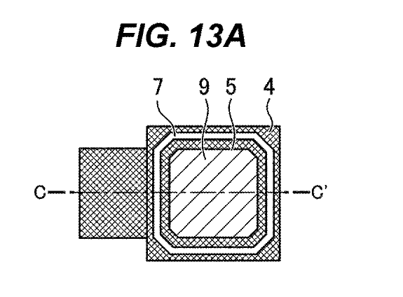

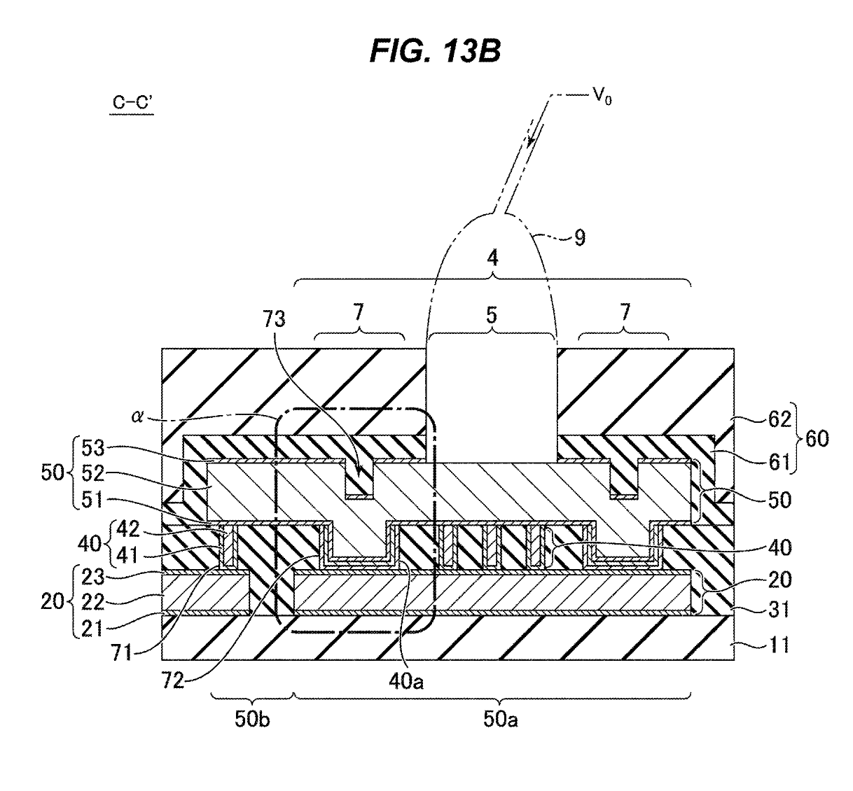

FIG. 13A is a schematic plan view of an example of the semiconductor device according to the Seventh Embodiment. FIG. 13A shows one bonding pad 4 of the semiconductor chip 2a which is a semiconductor device. In the bonding pad 4, the bonding wire 9 is provided on the entire surface of (the pad aluminum wiring layer of) the bonding pad 4 exposed to the pad opening portion 5.

FIG. 13B is a schematic cross-sectional view of an example of the semiconductor device according to the Seventh Embodiment. FIG. 13B shows a cross-section taken along the line CC′ in FIG. 13A and shows a portion higher than or equal to the interlayer insulating layer 11 positioned below the lower aluminum wiring layer 20 immediately below the pad aluminum wiring layer 50 of the bonding pad 4. Note that, for convenience of drawing, in FIG. 13B, the size of the pad opening portion 5 is reduced and the entire diagram is enlarged in the film thickness direction.

In the bonding pad 4, the bonding wire 9 is provided on the entire surface of the wiring metal 52 of the pad aluminum wiring layer 50 exposed to the pad opening portion 5. At this time, at a first glance, in the pad opening portion 5, the antireflection film 53 between the passivation film 60 and the wiring metal 52 is covered by the bonding wire 9, and thus it appears that water does not reach the antireflection film 53. However, there is a case where a small gap is generated between the passivation film 60 and the bonding wire 9 due to manufacturing variation, degradation caused by long-term use, and the like and water penetrates between the passivation film 60 and the bonding wire 9 and reaches the antireflection film 53. However, even in such a case, when the groove portion 7 is provided, it is possible to prevent a phenomenon in which the antireflection film 53 is oxidized and the volume of the antireflection film 53 expands to generate a crack in the passivation film 60.

Also in this case, the same effects as those of the First Embodiment can be obtained. The present embodiment can be applied to the other embodiments.

In addition, in the above-mentioned respective embodiments, the description is given by taking titanium nitride as antireflection film for example, but the respective embodiments are not limited to the example. The embodiments can be also applied to a film using a material which is easily oxidized and whose volume expands, when being used as the antireflection film.

Hereinbefore, while the invention made by the present inventor has been specifically described on the basis of the embodiments, it is needless to say that the present invention is not limited to the embodiments and the invention may be variously modified within a scope not departing from the gist of the invention. Each technique in the respective embodiments can be applied to other embodiments unless a technical contradiction is generated.

What is claimed is:

1. A semiconductor device comprising:
a metal wiring layer for a pad; and
an insulating layer which is provided so as to cover the metal wiring layer and which includes an opening portion from which a part of a surface of the metal wiring layer is exposed,
wherein the metal wiring layer includes
a first metal layer, and
a second metal layer which is provided over the first metal layer except for the opening portion, which is thinner than the first metal layer, and which has a reflectance lower than that of the first metal layer,
the metal wiring layer includes a groove portion in a predetermined region except for the opening portion,
the first metal layer protrudes, in an eaves shape, to the groove portion, and
the second metal layer on a side wall inside the groove portion is thinner than the second metal layer outside the groove portion.

2. The semiconductor device according to claim 1,
wherein a film thickness of the second metal layer is zero at at least a part of the side wall inside the groove portion.

3. The semiconductor device according to claim 1,
wherein the second metal layer includes titanium nitride, and
the first metal layer includes aluminum.

4. The semiconductor device according to claim 1,
wherein, when the metal wiring layer has a shape asymmetrical with respect to the opening portion, the groove portion is at least provided on the side of a larger area in the metal wiring layer except for the opening portion.

5. The semiconductor device according to claim 4,
wherein the groove portion surrounds the opening portion.

6. The semiconductor device according to claim 4,
wherein the metal wiring layer includes
a pad portion including a portion exposed to the opening portion, and
an extending portion coupled to a side surface of the pad portion, and
the groove portion is at least provided on the side of the extending portion as viewed from the opening portion.

7. The semiconductor device according to claim 4,
wherein at least one of two ends of the groove portion reaches an edge of the metal wiring layer.

8. The semiconductor device according to claim 1,
wherein a depth of the groove portion is larger than a depth of a via hole of a via for wiring of the metal wiring layer.

9. The semiconductor device according to claim 1,
wherein the metal wiring layer of the groove portion is a via for wiring of the metal wiring layer.

10. The semiconductor device according to claim 1, further comprising:
a bonding wire coupled to over the metal wiring layer in the opening portion,
wherein the bonding wire is wiring for applying a voltage greater than 0 V.

11. The semiconductor device according to claim 10,
wherein the bonding wire is buried in the entire opening portion.

12. A manufacturing method of a semiconductor device, comprising the steps of:
forming a via hole and a groove in an interlayer insulating layer over a lower layer wiring;
forming a buried metal layer so that the via hole is filled and the groove is filled up to a half-way depth;
forming, by a sputtering method, a first metal layer so as to cover the interlayer insulating layer and the buried metal layer;
forming, by a sputtering method, a second metal layer which is thinner than the first metal layer and whose reflectance is lower than that of the first metal layer, so as to cover the first metal layer;
forming a pad by etching the first metal layer and the second metal layer;
forming an insulating layer so as to cover the pad; and
forming an opening portion by etching the insulating layer and the second metal layer in a predetermined region except for a region including the groove so that a part of a surface of the first metal layer of the pad is exposed,
wherein the first metal layer protrudes, in an eaves shape, to the groove, and
the second metal layer on a side wall inside the groove is thinner than the second metal layer outside the groove.

13. The manufacturing method of a semiconductor device according to claim 12,
wherein a film thickness of the second metal layer is zero at at least a part of the side wall inside the groove.

14. The manufacturing method of a semiconductor device according to claim 12,
wherein the second metal layer includes titanium nitride, and
the first metal layer includes aluminum.

15. The manufacturing method of a semiconductor device according to claim 12,
wherein, when the metal wiring layer has a shape asymmetrical with respect to the opening portion, the groove portion is at least provided on the side of a larger area in the metal wiring layer except for the opening portion.

16. The manufacturing method of a semiconductor device according to claim 12,
wherein the groove surrounds the opening portion.

17. The manufacturing method of a semiconductor device according to claim 12,
wherein the metal wiring layer includes
a pad portion including a portion exposed to the opening portion, and
an extending portion coupled to a side surface of the pad portion, and
the groove is at least provided on the side of the extending portion as viewed from the opening portion.

18. The manufacturing method of a semiconductor device according to claim 17,
wherein at least one of two ends of the groove reaches an edge of the metal wiring layer.

19. The manufacturing method of a semiconductor device according to claim 12,
wherein a depth of the groove is larger than a depth of a via hole of a via for wiring of the metal wiring layer.

20. The manufacturing method of a semiconductor device according to claim 12,
wherein the metal wiring layer of the groove is a via for wiring of the metal wiring layer.
